(19) United States
(12) Patent Application Publication
(10) Pub. No.: US 2017/0012157 A1
(43) Pub. Date: Jan. 12, 2017

(54) SPECTRAL LIGHT SPLITTING MODULE AND PHOTOVOLTAIC SYSTEM

(71) Applicants: DOW GLOBAL TECHNOLOGIES LLC, Midland, MI (US); CALIFORNIAINSTITUTE OF TECHNOLOGY, Pasadena, CA (US)

(72) Inventors: Carissa Eisler, Santa Clarita, CA (US); Weijun Zhou, Sugar Land, TX (US); Emily D. Kosten, Pasadena, CA (US); Emily C. Warmann, Riverside, CA (US); Carrie E. Hofmann, Altadena, CA (US); Harry A. Atwater, South Pasadena, CA (US); Rebekah K. Feist, Midland, MI (US); James C. Stevens, Richmond, TX (US)

(21) Appl. No.: 15/107,315

(22) PCT Filed: Dec. 22, 2014
(86) PCT No.: PCT/US2014/071938

§ 371 Date: Jun. 22, 2016

Related U.S. Application Data
(60) Provisional application No. 61/920,140, filed on Dec. 23, 2013.

(51) Int. Cl. H01L 31/054; H01L 31/05

(52) U.S. Cl. CPC H01L 31/0547; H01L 31/0504

(57) ABSTRACT

A light splitting optical module that converts incident light into electrical energy, the module including a solid optical element comprising an input end for receiving light, a first side, and a second side spaced from the first side, a first solar cell adjacent to the first side of the solid optical element, and a second solar cell adjacent to the second side of the solid optical element. The first solar cell is positioned to absorb a first subset of incident light and reflect a first remainder of the incident light to the second solar cell through the solid optical element, wherein the first solar cell has a lower band gap than the second cell.

### CROSS-REFERENCE TO RELATED APPLICATIONS

This application claims priority to U.S. Provisional Patent Application No. 61/920,140, filed Dec. 23, 2013, the entire contents of which is incorporated herein by reference in its entirety.

### TECHNICAL FIELD

The present invention relates to photovoltaic devices that convert incident light into electrical energy. More specifically, the present invention relates to photovoltaic devices including a solid optical element with a plurality of photovoltaic cells configured in a parallelepiped arrangement.

### BACKGROUND

Photovoltaic cells, which may also be referred to as solar cells or PV cells, are useful for converting incident light, such as sunlight, into electrical energy. These cells can be provided as single junction solar cells, which have one specifically defined band gap that has an inherently low conversion efficiency. This is because a single photovoltaic cell is photovoltaically responsive only to a small portion of the broadband spectrum of the incident light and therefore converts only a small portion of incident light into energy. Photons whose energy is lower than the gap are not absorbed and subsequently converted, and in some cases can be parasitically absorbed and converted to wasted heat. Photons with energy greater than the band gap convert only part of their energy matching the energy gap into electrical energy while the excess energy is lost mainly as wasted heat. A number of ways of increasing the efficiency of solar cells have therefore been used and proposed.

One common method used for achieving higher photovoltaic efficiencies is to use multiple band gaps together to form a multi-junction solar cell. Such multi-junction solar cells are made of a system of different semiconductor materials that have different band gap energies that correspond with different parts of the solar spectrum. Only photons having an energy that matches or is slightly larger than the energy gap are used most efficiently. Thus, having a wider range of band gaps allows the system to convert more of the spectrum in a relatively efficient manner.

Conventionally, multi-junction cells are grown as monolithic stacks such that the light encounters the junctions from highest to lowest bandgap. Each semiconductor acts as a filter for the junction below it and thus each junction absorbs and converts light that has an energy between its own bandgap and the bandgap above it. Although traditional multi-junction tandem solar cells provide advantages over single junction solar cells, further efficiencies can be achieved through the use of light splitting optics that are used to split the incident solar radiation into multiple spectral bands and to direct those spectral bands towards different and corresponding solar cells. In this way, subcells can be grown and electrically connected independently, avoiding the problems of lattice and current matching. Each targeted cell is designed to have a band gap tailored to the spectral band directed to it in order to help maximize energy conversion. That is, the splitting optics partition the incident light into various segments or slices and then direct the slices independently to photovoltaic cells with appropriate band gaps.

Photovoltaic systems that utilize light splitting or spectrum splitting for improving solar conversion efficiency have been described in the patent and technical literature. Examples include U.S. Pat. Publication. Nos. 2009/0056788 (Gibson) and 2011/0284054 (Wanlass); Barnett et al., Progress in Photovoltaics: Research and Applications, “Very High Efficiency Solar Cell Modules,” 17:75-83 (2009); Imenes et al., Solar Energy Materials and Solar Cells, “Spectral Beam Splitting Technology for Increased Conversion Efficiency in Solar Concentrating Systems, A Review,” 84:19-69 (2004); McCambridge et al, Progress in Photovoltaics: Research and Applications, “Compact Spectrum Splitting Photovoltaic Module With High Efficiency.” 19:352-360 (2011); Mitchell et al., Progress in Photovoltaics: Research and Applications, “Four-junction Spectral Beam-Splitting Photovoltaic Receiver With High Optical Efficiency,” 19:61-72 (2011): and Peters et al., Energies, “Spectrally-Selective Photonic Structures for PV Applications,” 3:171-193 (2010).

While photovoltaic systems using light splitting technology with solar cells should theoretically improve the efficiencies of converting incident light into electrical energy, there is a need to provide systems that can realistically allow for even higher efficiencies with better light splitting optical structures and with more efficient configurations or arrangements of photovoltaic systems.

### SUMMARY

The present invention is directed to a photovoltaic system for converting incident light into electrical energy that may be referred to as a polyhedral specular reflector. The systems can be used to divide light to a series of single junction solar subcells or a series of tandem grown subcells. The systems can generally include an array of solar cells or photovoltaic cells arranged on opposite sides of a solid optical element, which can be used in combination with concentrating optics. The relatively high efficiency of these systems is the result of positioning each subcell so that it can absorb a specific subset of the light spectrum that is most efficiently absorbed by that cell, and then reflecting the remaining light through the solid optical element onto a subsequent cell that can then absorb its own subset of the light spectrum, wherein the first subcell is chosen to absorb a subset of the light spectrum with a lower bandgap than that of the second subcell. This process of absorbing and reflecting light at each solar cell continues, with differing amounts of light being available for absorption and reflection at each subsequent solar cell, until an optional back reflector is reached, which is generally at an opposite end of the array of cells from the input end. In an embodiment of the invention, at least two photovoltaic cells are used in combination with an optical concentrating element, wherein the cells are configured as a solid parallelepiped that aids in optical coupling of incident light.

In one aspect of the invention, a light splitting optical module is provided that converts incident light into electrical energy. The module includes a solid optical element including an input end for receiving light, a first side, and a second side spaced from the first side, a first solar cell adjacent to the first side of the solid optical element, and a second solar cell adjacent to the second side of the solid optical element. The module is configured to provide absorbance of incident light above at least one of the cells with the first solar cell that is positioned to absorb a first subset of incident light and reflect a first remainder of the incident light to the second solar cell through the solid optical element, wherein the first solar cell has a lower band gap than the second solar cell. This light splitting optical module may be combined with an optical concentrator element that collects and concentrates incident light, wherein the optical concentrator element directs light into the input end of the solid optical element. The module may comprise a long pass filter adjacent to the first side of the solid optical element, wherein the long pass filter transmits the first subset of incident light to the first solar cell and reflects a first remainder of the incident light to the second solar cell through the solid optical element, wherein the first solar cell is in optical communication with the long pass filter.

The light splitting module may further include a back solar cell having a higher bandgap than that of the first solar cell and/or a lower band gap than the second solar cell, the back solar cell being positioned at an opposite end of the solid optical element from the input end. The optical module may include the first and second solar cells and at least two additional solar cells arranged in a series so that a subset of light is sequentially absorbed by each solar cell and a remainder of the light is reflected, with decreasing amounts of light being available for absorption and reflection at each subsequent solar cell. The module can comprise a plurality of secondary optical concentrator elements, wherein each of the secondary optical concentrator elements is in optical communication with one of the first solar cell, the second solar cell, and the at least two additional solar cells.

In another aspect of the invention, a photovoltaic system is provided that includes a plurality of light splitting optical modules that convert incident light into electrical energy. Each module includes a solid optical element comprising an input end for receiving light, a first side, and a second side spaced from the first side, a first solar cell adjacent to the first side of the solid optical element, and a second solar cell adjacent to the second side of the solid optical element. Each module is configured to provide absorbance of light above at least one of the cells with its first solar cell that is positioned to absorb a first subset of incident light and reflect a first remainder of the incident light to the second solar cell through the solid optical element. In addition, the modules are adjacent to each other and are vertically arranged so that the input ends of each of the solid optical elements are on different horizontal planes from the input ends of the solid optical elements of the other modules. With this system, each of the plurality of light splitting modules can further comprise an optical concentrator element that collects and concentrates incident light and directs the incident light into the input end of its respective solid optical element. In addition, the first solar cell of at least one of the modules has a lower band gap than the second solar cell of the respective module.

### BRIEF DESCRIPTION OF THE DRAWINGS

The present invention will be further explained with reference to the appended Figures, wherein like structure is referred to by like numerals throughout the several views, and wherein:

FIG. 1 is a side schematic view of the parallelepiped arrangement of solar cells of a light splitting optical module of the invention;

FIG. 2 is a graph showing the filters suitable for use and their corresponding performances in a module of the type illustrated in FIG. 1;

FIG. 3 is a perspective view of a prior art arrangement of plural adjacent light splitting optical modules with individual cell concentrators, along with a compound parabolic concentrator for each module, wherein the input ends of the modules are generally on the same horizontal plane;

FIG. 4 is a perspective view of an exemplary arrangement of multiple light splitting optical modules with individual cell concentrators, along with a compound parabolic concentrator for each module, wherein each of the modules is spaced horizontally from each adjacent module, and wherein the input ends of the modules are generally on the same horizontal plane;

FIG. 5 is a perspective view of an exemplary arrangement of multiple light splitting optical modules with individual, cell concentrators, wherein each of the modules is spaced from each adjacent module, wherein the input ends of the modules are generally on the same horizontal plane;

FIG. 6 is a perspective view of an arrangement of multiple light splitting optical modules with individual cell concentrators, along with a compound parabolic concentrator for each module, wherein the modules are vertically staggered relative to each adjacent module, in accordance with the invention;

FIG. 7 is a perspective view of an arrangement of multiple light splitting optical modules with individual cell concentrators, wherein the modules are vertically staggered relative to each adjacent module, in accordance with the invention; and

FIG. 8 is a graphical representation of an efficiency map as a function of subcell external radiative efficiency (EFE) for a particular optical system arrangement of the invention.

### DETAILED DESCRIPTION

The embodiments of the present invention described below are not intended to be exhaustive or to limit the invention to the precise forms disclosed in the following detailed description. Rather the embodiments are chosen and described so that others skilled in the art may appreciate and understand the principles and practices of the present invention. All patents, pending patent applications, published patent applications, and technical articles cited throughout this specification are incorporated herein by reference in their respective entireties for all purposes.

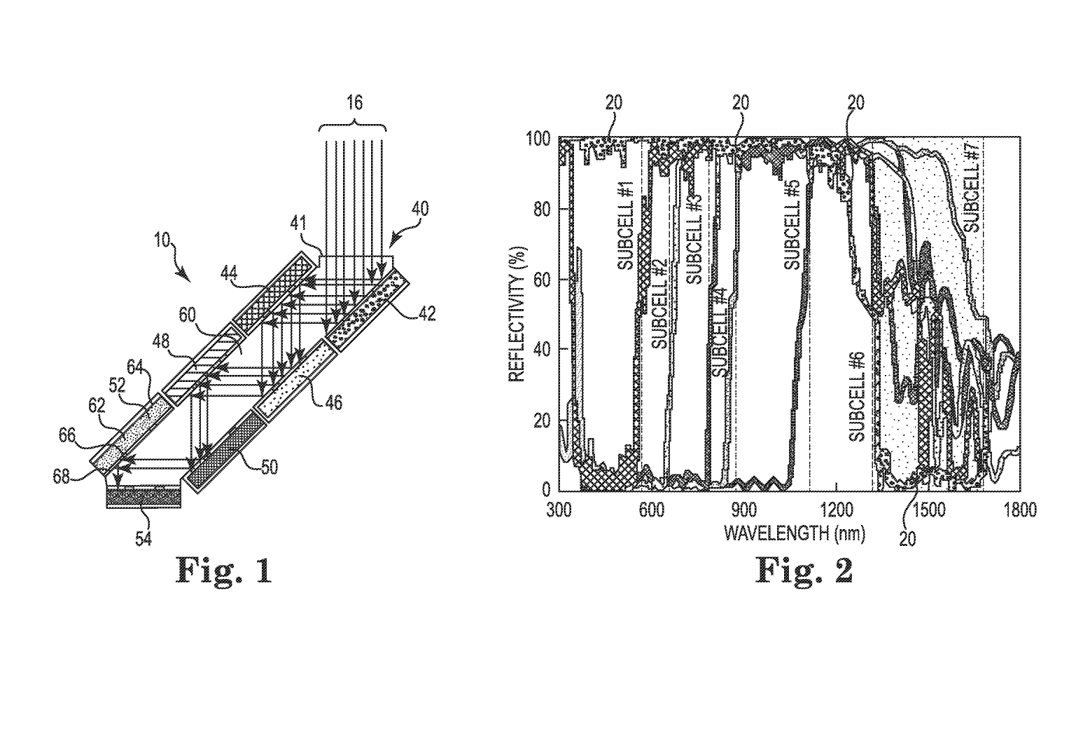

Referring now to the figures, and initially to FIG. 1, an exemplary embodiment of a light splitting optical module 10 is illustrated. Module 10 can be used for photovoltaic conversion of incident light 16 into electrical energy, as will be described in further detail below. As is shown, the optical module 10 is generally provided in the form of a parallelepiped, wherein the particular arrangement of structures that make up the parallelepiped structure are provided with properties specific to the invention.

Optical module 10 includes an input area 40 at the top of the parallelepiped structure into which light enters the module. The area 40 can optionally include an anti-reflective coating or material 41 positioned on the top of the parallelepiped into which incident light 16 enters. The anti-reflective coating 41 can help to maximize the amount of incident light entering the optical module 10. It is noted that the incident light 16 described and illustrated herein will typically be white light that exits from a concentrator and/or incident light that is provided directly by a light source, such as the sun. For illustrative purposes, this incident light 16 is illustrated in FIG. 1 as being split into seven different spectral bands, which are schematically illustrated with seven different colors in the figures. These spectral bands will be processed by solar cells of the system described below. However, a different number of cells can instead be used in the parallelepiped structure, and in such a case, a representative illustration would split the light into a corresponding number of spectral bands.

The optical module 10 includes two or more photovoltaic cells that are independently tuned to absorb and convert a predefined subset of the light spectrum to electrical power and to reflect the remainder of the light to which it is subjected. That is, light that is not absorbed by a cell will travel to the next cell in the series. To minimize losses from this traveling process, filters can be used to reflect light that cannot be converted in the cell and prevent it from, traveling through the cell. Generally, at least a first photovoltaic cell photovoltaically responds most efficiently to a first spectral bandwidth portion of the incident light and the second photovoltaic cell photovoltaically responds most efficiently to a second spectral bandwidth portion of the incident light, etc., wherein the bands are arranged so that the lowest energy light is transmitted to the first subcell, which is the lowest bandgap subcell, and reflect all of the higher energy light to the second solar cell, which has a higher bandgap than the first subcell. For purposes of illustration, optical module 10 includes seven differently tuned photovoltaic cells, including first cell 42, second cell 44, third cell 46, fourth cell 48, fifth cell 50, sixth cell 52, and seventh cell 54, although it is understood that a different number of photovoltaic cells may be used. Each of the seven photovoltaic cells may be either a single or multiple junction photovoltaic cell.

As shown, the photovoltaic cells of the optical module 10 are arranged so that three of the cells are positioned adjacent to each other in a row along one side of a parallelepiped support structure 60, and so that another three cells are positioned adjacent to each other in a row along an opposite side of the support structure 60. The rows are generally arranged to be at an angle to the input area 40 of the optical module 10, such as at an approximately 45-degree angle. The illustrated light entry angle (i.e., normal incidence) will be typical for light that has not passed through a concentrator, in that when a concentrator is used, at least some of the light will enter at an angle that is not normal to the plane at which the light enters the system. In this way, when incident light 16 enters the input area 40 of the optical module 10, it will be directed at a 45 degree to a surface of the first cell 42 that is facing toward the support structure 60, and light that is reflected from this surface will he directed toward the second cell 44 at the same angle (i.e., approximately 45 degrees). That is, when the cells are arranged in this manner, reflected light will move through the support structure 60 at an angle that is generally perpendicular to the angle at which it contacted the previous photovoltaic cell.

It is further understood that the photovoltaic cells are generally parallel to each other across the support structure 60, although they can be angled at least slightly relative to each other (e.g., angled at a 1-2 degree angle relative to each other, or angled at an angle of less than 1 degree or greater than 2 degrees). In such an embodiment, if the light enters very near normal incidence, the absorption and reflection of the various subsets of the light spectrum will be at least slightly less efficient than in an optical module where the cells are parallel to each other, since the path that reflected light takes will be slightly different when the cells are parallel than when they are not parallel. That is, the structures shown and described herein are generally directed to a parallelepiped, but other geometries are also contemplated that can provide for similar movement of light along a structure.

The support structure 60 of an embodiment of the invention can be made of a solid material, such as glass, plastic, or GaP, for example, although other materials are contemplated. Generally, the material for the support structure 60 can be any material with a relatively high index of refraction that is transparent across most of the solar spectrum. Using a support structure with a relatively high index of refraction can advantageously provide for higher refraction of the incoming light, which will allow the structure to both incorporate higher concentration and also minimize the angular spread of the incoming light. This will help to minimize optical losses. The material of the support structure 60 can also be transparent and non-scattering to allow for smooth movement of light through the module 10.

The optical module 10 further includes photovoltaic cell 54 positioned at the opposite end from the input end 40. Cell 54 is generally parallel to input area 40 of the optical module 10, but can be at least slightly angled relative to it. In such an arrangement, the cell 54 will also be arranged at an approximate 45-degree angle to the photovoltaic cells that are adjacent to it (e.g., photovoltaic cells 50, 52 of this figure). The cell 54 can optionally include a filter, and can be replaced with a reflector that can reflect any unabsorbed light back through the structure for possible conversion.

Each of the photovoltaic cells of the module 10 can include a number of features, such as a central cell active region 62 (shown relative to solar cell 52, although the description can apply to all of the cells in the structure), a back contact and reflector 64, one or more contact grid areas 66, and a layer 68 that can include an antireflective coating/filter and adhesive. Each of the photovoltaic cells is generally tuned or has band gap characteristics that allow it to absorb a certain spectral bandwidth portion of the incident light to which it is subjected, and then includes a reflector that allows it to reflect the portion that is not absorbed on the first path. The cells can also have additional optics (e.g., plasmonic structures) to improve the light trapping capabilities of the system. Each of the photovoltaic cells of the exemplary embodiment of module 10 is described generally below, although it is understood that the wavelengths and colors of this embodiment represent only one of many ways that the incident light can be split. The colors of the light rays are only for illustrative purposes. The bandgaps described herein may be adjusted to accommodate the number of cells of the particular parallelepiped. In addition, it may be possible to split the system into two sets of cells, which will allow for the addition of another light splitting element to the design (e.g., dichroic splitter).

The filters can be provided in a number of ways. For one example, a nanoimprinting process can be used to pattern an optical filter for each cell onto the parallelepiped, rather than on the cell. For another example, the filter can be molded. Further, with any of the structures used, flexible circuitry can be used to ease assembly, wherein the cells can be assembled onto a sheet that can be formed to fit the parallelepiped or other geometry.

The cells or subcells used with the systems of the invention are electrically independent, and may include an insulating material (e.g., an insulating polymer) between them, due to the proximity of cells to one another. It is further contemplated that the structure of the optical module can allow for photon recycling between cells, since they are optically active with each other.

As is described and illustrated herein, the subcells can either be used to split the light themselves (Le., to absorb only what is above their bandgap and reflect everything else with their back reflectors), or filters arc put on the front of the subcells to help in case there are parasitic losses. For example, if a cell that is designed to absorb purple light parasitically absorbs some green light, then when a green photon hits it, it could be absorbed and therefore lost at that reflector. Having a filter helps to mitigate the losses because only the purple photons are let through and the green photons are blocked from entering. In a configuration wherein each cell has its own concentrator (discussed below), filters are used so that the concentrators do not send light out of the structure instead of allowing it to continue down the structure until it reaches the correct subcell.

First photovoltaic cell 42 is tuned (e.g., it has band gap characteristics) to absorb with wavelengths from 1319 nm to 1675 nm, which is represented by the red or deep red light ray. The spectral bandwidth portion of the incident light with photon energy higher than this wavelength range will be reflected to the second photovoltaic cell 44, without the penalty of possible second harmonic reflections in the transmission bandwidth.

Second photovoltaic cell 44 is tuned (e.g., it has band gap characteristics) to absorb the spectral bandwidth portion of incident light including wavelengths from 280 nm to 577 nm, which is represented by the indigo light ray. The spectral bandwidth portion of the incident light that is outside of this wavelength range will ideally be reflected toward the photovoltaic cell 46, as is shown in FIG. 1.

Third photovoltaic cell 46 is tuned (e.g., it has band gap characteristics) to absorb the spectral bandwidth portion of incident light including wavelengths from 577 nm to 674 nm, which is represented by the blue light ray. The spectral bandwidth portion of the incident light that is outside of this wavelength range will ideally be reflected toward the photovoltaic cell 48.

Fourth photovoltaic cell 48 is tuned (e.g., it has band gap characteristics) to absorb the spectral bandwidth portion of incident light including wavelengths from 674 nm to 785 nm, which is represented by the blue-green light ray. The spectral bandwidth portion of the incident light that is outside of this wavelength range will ideally be reflected toward the photovoltaic cell 50.

Fifth photovoltaic cell 50 is tuned (e.g., it has band gap characteristics) to absorb the spectral bandwidth portion of incident light including wavelengths from 785 nm to 873 nm, which is represented by the green-yellow light ray. The spectral bandwidth portion of the incident light that is outside of this wavelength range will be reflected toward the photovoltaic cell 52.

Sixth photovoltaic cell 52 is tuned (e.g., it has band gap characteristics) to absorb the spectral bandwidth portion of incident light including wavelengths from 873 nm to 1078 nm, which is represented by the yellow light ray. The spectral bandwidth portion of the incident light that is outside of this wavelength range will ideally be reflected toward the photovoltaic cell 54.

Seventh photovoltaic cell 54 is tuned (e.g., it has band gap characteristics) to absorb the spectral bandwidth portion of incident light including wavelengths from 1078 nm to 1319 nm, which is represented by the orange light ray. In a system where all of the incident light enters the parallelepiped normally, all or most of the light with photons of a high enough energy will he absorbed by the time it reaches this cell 54. However, with concentration and non-idealities in the system, some of the light will not have been directed to a cell that could absorb it. This will be the portion of the light that will reach the cell 54, some of which will be absorbed, and the remainder of which can be reflected back up into the parallelepiped, where it can be reflected through the cells in reverse order (i.e., sixth cell through first cell) until it is either absorbed by one of the cells or escapes from the system.

In operation, the seven photovoltaic cells 42, 44, 46, 48, 50, 52, 54 are arranged such that the entering and reflecting light will be absorbed first by the lowest band gap subcell 42, wherein a long pass filter can be configured to transmit lower energy light to this low band gap subcell 42 and reflect all higher energy light to the higher bandgap subcell 44, without the penalty of possible second harmonic reflections in the transmission bandwidth. After the first subcell 42, the light can then be reflected in a number of different orders that are contemplated by the present invention. For one example, cell 42 is the lowest bandgap subcell, the cell 44 is the highest bandgap subcell, and any remaining cells (e.g., cells 46-54) are arranged in decreasing order of their respective bandgaps (i.e., cell 46 has a higher bandgap than that of cell 48, cell 48 has a higher bandgap than that of cell 50, etc.). In a variation of this example, cells 46-54 are arranged in a different order than in an order of decreasing bandgap cells, and may be arranged randomly relative to the order of their respective bandgaps. As is schematically illustrated in FIG. 1, with each sequential absorption and reflection of portions of the incident light, fewer spectral bandwidth portions will move to the next photovoltaic cell in the sequence. Thus, the last colors to be absorbed and/or reflected will travel the greatest distance through the optical module 10.

With any of the embodiments described herein, the absorbed light from the photovoltaic cells can be in operative communication with one or more electrical leads in order to capture the light for useful transmission thereof.

The following table shows exemplary band gaps for a seven-cell parallelepiped design of an optical module, such as that described above, with exemplary III-V materials and growth substrates (for lattice matching):

TABLE 1

| E_{g} (eV) | III-V Alloy | Substrate |
|---|---|---|
| 0.74 | In_{0.53}Ga_{0.47}As | InP |
| 0.94 | In_{0.71}Ga_{0.29}As_{0.62}P_{0.38} | InP |
| 1.15 | In_{0.87}Ga_{0.13}As_{0.28}P_{0.72} | InP |
| 1.42 | GaAs | GaAs |
| 1.58 | Al_{0.1}Ga_{0.9}As | GaAs |
| 1.84 | Ga_{0.51}In_{0.49}P | GaAs |
| 2.15 | Al_{0.20}Ga_{0.32}In_{0.48}P | GaAs |

These alloys are only intended to be exemplary and provide choices in the III-V family that can therefore provide for good absorption and performance due to their high quality growth/direct band gaps. In addition, these alloys can provide an ability to be grown lattice-matched (i.e., without defects on the growth substrate) for higher material quality. The materials can include tunable properties, specifically to a cell band gap within +/−0.1 eV of the desired state, such that even if the band gaps vary slightly, the efficiencies will remain similar.

The photovoltaic cells shown in the figures are illustrated as single junction cells; however, it is understood that the cells may instead be multi-junction cells. The cells may be thin-film or epitaxially lifted off cells, for example. Embodiments of the invention may also include the use of narrow filters and/or anti-reflective coating(s) in combination with the solar cells. If anti-reflective materials are used, they may include 3-10 layers for example, and may include multiple refractive index materials.

In one exemplary embodiment, the overall height of a particular light splitting optical module 10 can be approximately 8 mm high, with the photovoltaic cells of the structure having a length of approximately 2.8 mm. Each of the photovoltaic cells of a particular optical module 10 can have the same physical dimensions, or at least one of the cells can have dimensions that are at least slightly different than the other cells of the structure. The cell size and area can be tuned to adjust the spectrum independently, such that the embodiments are very amenable to any series/parallel electrical configuration.

Although the optical module 10 is illustrated and described as having seven solar cells, more or less than seven of such solar cells can instead be provided for a particular optical module, wherein the particular subset of the light spectrum that each of the cells will absorb and reflect will then be different than that described above for a seven cell structure. In addition, the wavelength ranges associated with each of the solar cells described above can either be smaller or larger, depending on the particular materials used, the tuning of the system, the efficiency of the optical design for different wavelengths, etc.

The relatively high efficiencies that can be achieved by the photovoltaic systems of the invention occur for a number of reasons. That is, positioning the first solar cell with a lower band gap before a solar cell having a higher band gap minimizes issues that can result from using a shortpass filter first that is designed to reflect unusable photons away from the first subcell while still allowing for transmission of the entire bandwidth of interest. The ordering of junctions discussed herein in accordance with the present invention allows the range of the reflection band to be reduced and higher optical efficiency filters to be made.

It is further noted that the higher index material can help to “straighten out” entering light rays via light refraction, which will help to direct light along a desired path, thereby allowing for higher concentration. Higher concentration allows for higher subcell performance, therefore, it can be advantageous to couple concentration and a high index support structure to achieve the highest efficiencies. In addition, embodiments of the invention allow for the use of many cells, each of which can have a reflector that provides for better absorption and thinner cells to maximize the voltage available from a solar cell.

With the present invention, the arrangement of cells with the lowest bandgap cell first can provide certain optical efficiency advantages by recovering photons of short wavelengths that might otherwise be misallocated during the light splitting process. Any optical losses will require higher concentration to reach a desired optical efficiency (i.e., to compensate for those losses). Therefore, reducing optical losses of the filter set will increase the optical efficiency and lead to a smaller minimum concentration to achieve that module efficiency.

While the description above involves an arrangement of cells that includes a first cell 42 with the lowest band gap of the optical module 10, a second cell 44 having the highest band gap of the module 10, and the remaining cells having progressively decreasing band gaps, all of which are higher than the band gap of cell 42, it is understood that the cells can instead be arranged in a different order. Far one example, the first cell 42 can have the lowest band gap of the optical module, and then the remaining cells can be arranged in any order desired for matching a corresponding filter design for optimal light splitting and module efficiency. In another example, the first cell can have any band gap that is not the highest of the module 10, and the remaining cells can then be arranged in an order that allows for optimal light splitting and module efficiency for a given filter design set.

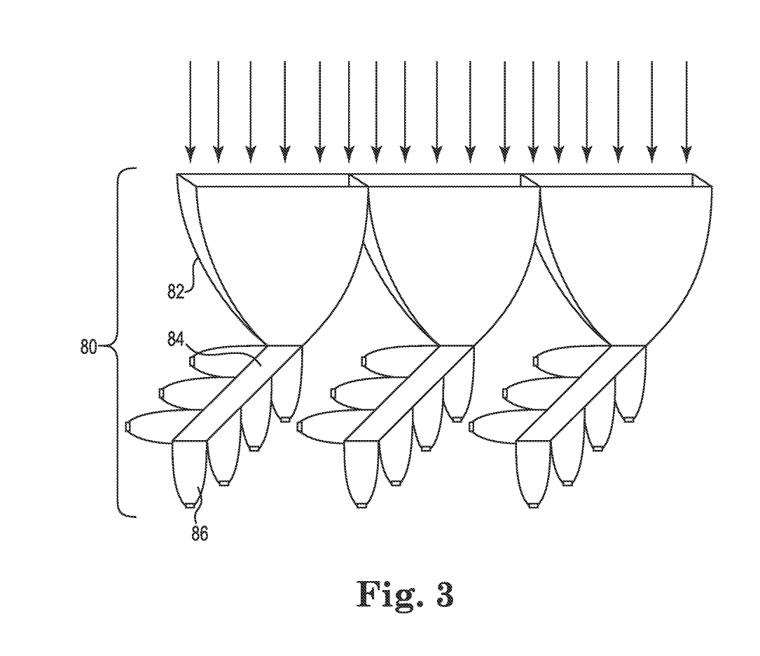

FIG. 2 is a graph showing the filters suitable for use and their corresponding performances in a module of the type illustrated in FIG. 1. In this embodiment, a long pass filter (the performance of which is shown with line 20 near the top of the graph) is placed on top of the module that reflects 350-1320 nm wavelength light to the downstream filter and transmits light of 1320 nm and longer wavelengths, which will he converted by the lowest band gap cell. With the use of a long pass filter first in the light splitting optical module, all of the short pass filters only need to reflect out to 1320 nm.

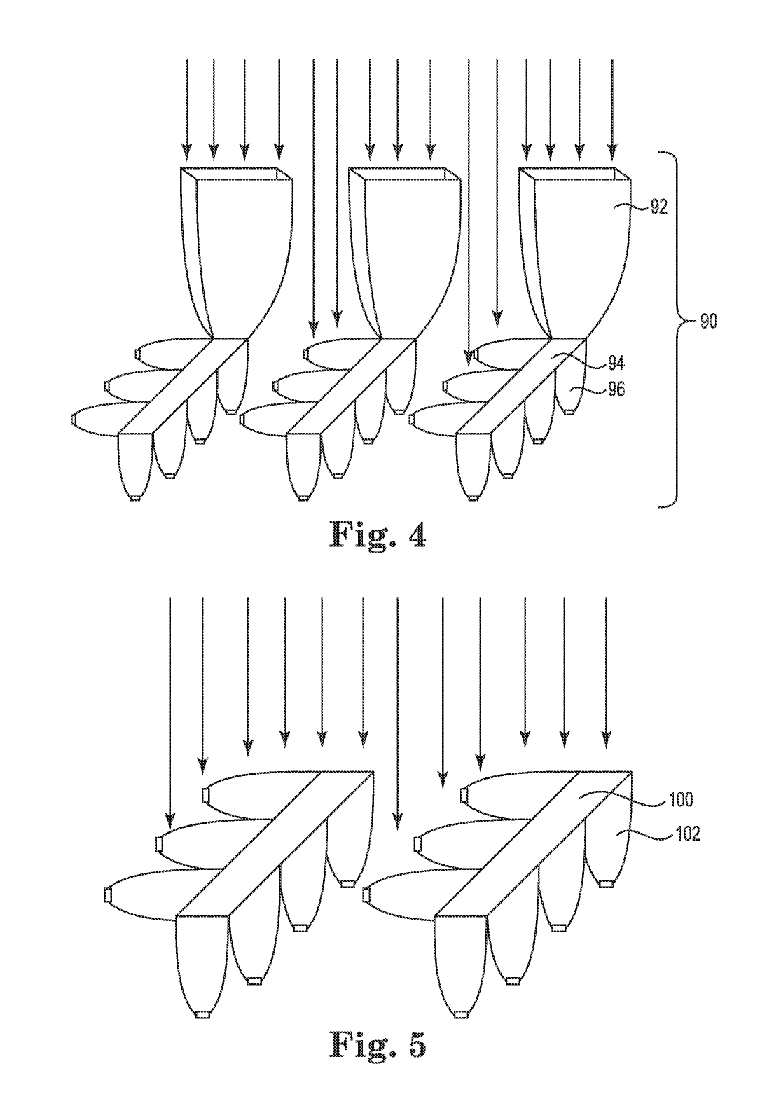

FIGS. 3-7 illustrate a number of arrangements of multiple light splitting optical modules into a larger system, which may include the modules described above and/or other modules. In any case, multiple optical modules are arranged in systems that can optionally include a primary optical concentrator and/or secondary optical concentrator(s) associated with each cell. Referring first to FIG. 3, multiple photovoltaic systems 80 are shown, each of which includes a primary optical concentrator 82 (e.g., compound parabolic concentrator) and light splitting optical module 84, which may be the same or different from the modules 10 described above. The systems 80 also include a series of secondary concentrators 86. As is discussed above relative to system 10, the module 84 of this figure includes two or more photovoltaic cells arranged generally into a parallelepiped structure, wherein FIG. 3 provides an exemplary embodiment with seven of such cells, each of which includes one or more filters. Six of such cells are on the sides of the parallelepiped and one cell is on the bottom. With this embodiment, additional or secondary concentrators 86 are provided to concentrate light from each filter or cell, thereby providing a light path that includes primary concentration, light splitting, and then secondary concentration.

As shown in FIG. 3, addition of the secondary concentrators 86 makes the optical modules considerably wider, which dictates certain parameters relative to the placement of modules next to each other. With regard to FIG. 3, the systems 80 are positioned so that their respective secondary concentrators are as close as possible to each other in a row. The systems 80 are therefore provided with relatively large primary concentrators so that the area in which light enters the systems includes multiple primary concentrators arranged in a relatively tightly packed manner.

However, in cases where it is desirable for photovoltaic systems to instead include somewhat smaller primary concentrators when the systems also include secondary concentrators, the systems will be spaced at least slightly from each other, such as is shown in FIG. 4 with systems 90, each of which includes a primary optical concentrator 92 (e.g., a compound parabolic concentrator), a light splitting optical module 94, and a series of secondary concentrators 96. As shown, incoming incident light will not enter any of the photovoltaic systems in the spaces between the systems 90, and this light will therefore be wasted.

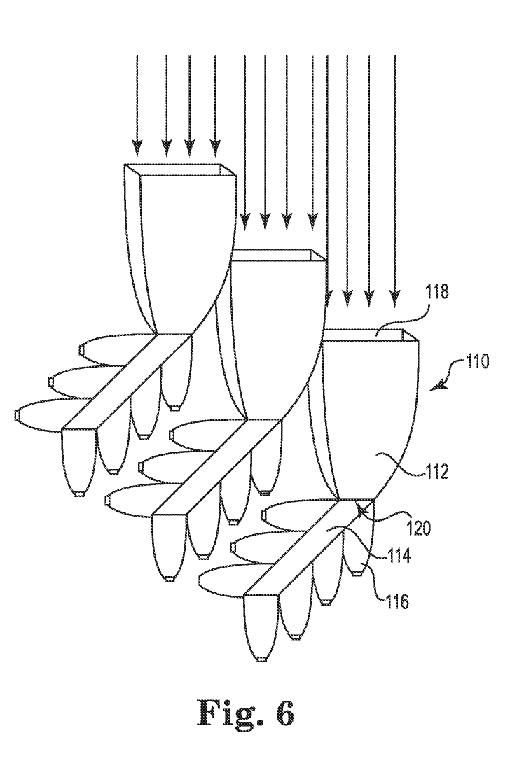

Similarly, FIG. 5 illustrates multiple modules 100, each of which includes multiple secondary concentrators 102, wherein these modules do not have primary concentrators. As shown, arranging these modules 100 as close to each other as possible will result in a considerable amount of incident light being directed to areas other than the input areas of the modules 100.

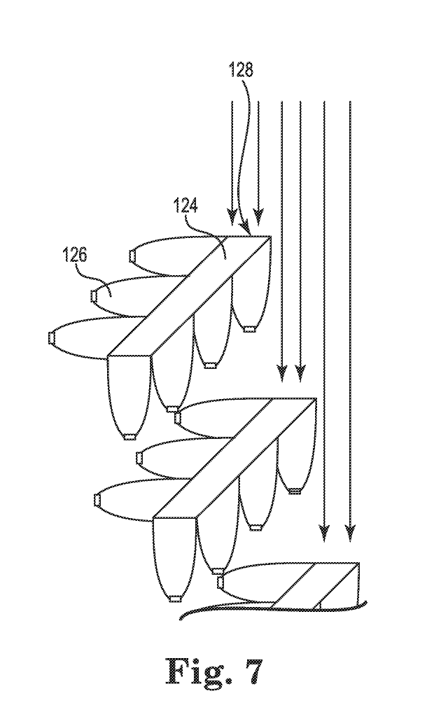

FIGS. 6 and 7 illustrate arrangements of multiple photovoltaic systems relative to each other in a manner that effectively utilizes a maximum amount of incoming incident light. In particular, FIG. 6 illustrates multiple photovoltaic systems 110, each of which includes a primary optical concentrator 112 (e.g., compound parabolic concentrator), a light splitting optical module 114, and a series of secondary concentrators 116. In this embodiment, the systems 110 are vertically arranged so that the input ends 118 of each of the concentrators 112 are on different horizontal planes from the input ends 118 of the other concentrators 112. Also, input ends 120 of the modules 114 are on different horizontal planes from the input ends 120 of other adjacent modules so that their primary optical concentrators 112 are touching or nearly touching. In this way, spaces between adjacent photovoltaic systems can be minimized or eliminated, thereby allowing for more effective capture of a higher percentage of incident light.

FIG. 7 provides for a similar arrangement of multiple light splitting optical modules 124, each of which includes a series of secondary concentrators 126. In this embodiment, the modules 124 are vertically arranged so that the input ends 128 of each of the modules 124 are on different horizontal planes from the input ends 128 of the other modules 124. In this way, spaces between adjacent modules can be minimized or eliminated, thereby allowing for more effective capture of a higher percentage of incident light.

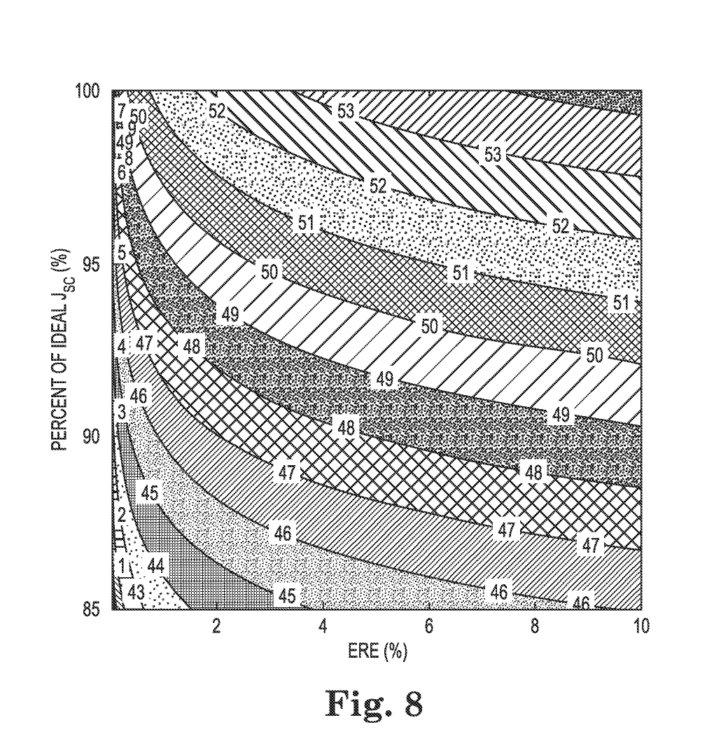

FIG. 8 is a graphical representation of an efficiency map as a function of subcell external radiative efficiency (EFE) and percent ideal short circuit current (% Ideal J_{sc}) for a particular optical system arrangement of the invention. In particular, this Figure illustrates a configuration that utilizes the module 10 described above relative to FIG. 1, in a vertical arrangement of the type shown in FIG. 7, such that an initial concentration of 4× and a secondary concentration of 77× will yield an overall concentration of 209×. Approximate 50% efficiency can be achieved assuming a relatively high subcell quality (i.e., greater than 3% ERE and greater than 93% ideal short circuit current.

The present invention has now been described with reference to several embodiments thereof. The entire disclosure of any patent or patent application identified herein is hereby incorporated by reference. The foregoing detailed description and examples have been given for clarity of understanding only. No unnecessary limitations are to be understood therefrom. It will be apparent to those skilled in the art that many changes can be made in the embodiments described without departing from the scope of the invention. Thus, the scope of the present invention should not be limited to the structures described herein, but only by the structures described by the language of the claims and the equivalents of those structures.

1. A light splitting optical module that converts incident light into electrical energy, the module comprising:
a solid optical element comprising an input end for receiving light, a first side, and a second side spaced from the first side;
a first solar cell adjacent to the first side of the solid optical element; and
a second solar cell adjacent to the second side of the solid optical element;
wherein the module is configured to provide absorbance of incident light above at least one of the cells with the first solar cell that is positioned to absorb a first subset of incident light and reflect a first remainder of the incident light to the second solar cell through the solid optical element, wherein the first solar cell has a lower band gap than the second solar cell.

2. The optical module of claim 1 in combination with an optical concentrator element that collects and concentrates incident light, wherein the optical concentrator element directs light into the input end of the solid optical element.

3. The optical module according to claim 1, further comprising a long pass filter adjacent to the first side of the solid optical element, wherein the long pass filter transmits the first subset of incident light to the first solar cell and reflects a first remainder of the incident light to the second solar cell through the solid optical element.

4. The optical module of claim 3, wherein the first solar cell is in optical communication with the long pass filter.

5. The optical module of claim 1, further comprising:
a first pair of solar cells comprising the first solar cell and the second solar cell spaced from each other across a width of the solid optical element; and
a second pair of solar cells comprising a third solar cell and a fourth solar cell spaced from each other across the width of the solid optical element, wherein the first pair of solar cells is adjacent to the second pair of solar cells;
wherein the first and second pairs of solar cells comprise a portion of a parallelepiped structure.

6. The optical module according to any of claims claim 14, further comprising a back solar cell having a higher bandgap than the bandgap of the first solar cell, the back solar cell being positioned at an opposite end of the solid optical element from the input end.

7. The optical module of claim 6, wherein the back solar cell has a lower band gap than the second solar cell.

8. The optical module of claim 1, further comprising an arrangement of the first and second solar cells and at least two additional solar cells in a series so that a subset of light is sequentially absorbed by each solar cell and a remainder of the light is reflected, with decreasing amounts of light being available for absorption and reflection at each subsequent solar cell.

9. The optical module according to claim 14, further comprising a plurality of secondary optical concentrator elements, wherein each of the secondary optical concentrator elements is in optical communication with one of the solar cells of the module.

10. The optical module according to claim 9, in combination with an optical concentrator element that collects and concentrates incident light, wherein the optical concentrator element directs light into the input end of the solid optical element.

11. A photovoltaic system composing a plurality of light splitting optical modules that convert incident light into electrical energy, wherein each module comprises:
a solid optical element comprising an input end for receiving light, a first side, and a second side spaced from the first side;
a first solar cell adjacent to the first side of the solid optical element; and
a second solar cell adjacent to the second side of the solid optical element;
wherein each module is configured to provide absorbance of light above at least one of the cells with its first solar cell that is positioned to absorb a first subset of incident light and reflect a first remainder of the incident light to the second solar cell through the solid optical element; wherein the modules are adjacent to each other and are vertically arranged so that the input ends of each of the solid optical elements are on different horizontal planes from the input ends of the solid optical elements of the other modules.

12. The photovoltaic system of claim 11, wherein each of the modules are horizontally arranged so that all of the incoming incident light will be directed toward the planar input end of one of the solid optical elements.

13. The photovoltaic system according to claim 11, wherein each of the plurality of light splitting modules further comprises an optical concentrator element that collects and concentrates incident light and directs the incident light into the input end of its respective solid optical element.

14. The photovoltaic system according to claim 11, wherein the first solar cell of at least one of the plurality of light splitting modules has a lower band gap than the second solar cell of the respective light splitting module.

15. The photovoltaic system according to claim 11, wherein at least one of the modules further comprises a plurality of secondary optical concentrator elements, wherein each of the secondary optical concentrator elements is in optical communication with one of the first solar cell and the second solar cell.
